(19) United States
(12) Patent Application Publication
(10) Pub. No.: US 2010/0085047 A1
(43) Pub. Date: Apr. 8, 2010

(54) METHOD FOR DETECTING PARAFFIN WAX AND ASPHALTENE CONTENT IN OIL

(75) Inventors: Ivan Vladimirovich Nikolin, Moscow (RU); Sergey Sergeevich Safonov, Moscow (RU); Vladimir Dmitrievich Skirda, Kazan (RU); Nikolay Viktorovich Shkalikov, Kazan (RU)

Correspondence Address: SCHLUMBERGER-DOLL RESEARCH;ATTN: INTELLECTUAL PROPERTY LAW DEPARTMENT, P.O. BOX 425045, CAMBRIDGE, MA, 02142, US

(73) Assignee: Schlumberger Technology Corporation

(21) Appl. No.: 12/493,561

(22) Filed: Jun. 29, 2009

Related U.S. Application Data
(63) Continuation of application No. PCT/RU07/00743, filed on Dec. 27, 2007.

(30) Foreign Application Priority Data
Dec. 28, 2006 (RU) 2006146961

(51) Int. Cl. G01R 33/44

(52) U.S. Cl. 324/307

(57) ABSTRACT

This invention relates to geology, geochemistry, oil refinery and petroleum chemistry and can be implemented for determination of paraffin and asphaltene concentration in oil, in particular, for analysis of heavy oils and bitumens. To determine concentration of paraffins and asphaltenes in oil, three crude oil samples are extracted; two extracted samples are dissolved in a solvent and the solvent alongside with light oil fractions is then removed; meanwhile, asphaltenes are removed from one of the solvent-treated samples. A nucleic magnetic resonance method is employed for measuring free inductance drop-down curves for all three samples; thereafter, a ratio of solid hydrogen-containing fractions suspended in oil, to liquid hydrogen-containing fractions is defined. The paraffin concentration is judged by the content of solid hydrogen-containing fractions in the solvent-treated sample, from which asphaltenes have been removed. The asphaltene concentration is judged by the content of solid hydrogen-containing fractions in the other solvent-treated sample, with the consideration of the defined concentration of paraffins. The concentration of paraffins and asphaltenes in original oil is determined based on the defined paraffin-to-asphaltene ratio in solid hydrogen-containing fractions.

This invention relates to geology, geochemistry, oil refinery and petroleum chemistry, namely, to the determination of paraffin wax and asphaltene content in oil, which could be of particular usefulness in analyzing heavy oils and bitumens.

### BACKGROUND OF THE INVENTION

Data on oil composition, in particular, on the concentration of heavy (solid-body) fractions, significantly simplify the optimization of oil production and oil refinery processes. Nevertheless, this information is not always available due to complexity, ambiguousness and high cost of state-of-the-art methods for determining concentrations of some oil components. While light oil fractions can be separated through simple distillation and rectification methods, simple methods do not allow us to determine the concentration of the heaviest oil fractions (paraffin wax and asphaltenes).

Advanced methods for paraffin wax and asphaltene concentration detection in oils are standardized as per GOST 11851 and GOST 11858, respectively.

The standard GOST 11851-85 “Oil Paraffin Wax Determination Method”, approved by the USSR Gosstandart of 21 May 1985, establishes two methods (A and B) for determination of the paraffin wax weight ratio in oil. Method A calls for a preliminary removal of asphalt-resinous matters from oil, the extraction and adsorption of the removed asphalt-resinous matters, with a follow-up separation of the paraffin with an acetone/toluene mixture at a temperature of minus 20° C. Method B calls for a preliminary removal of asphalt-resinous matters from oil using a vacuum distillation process with a fraction extraction at temperatures of 250-550° C., and the paraffin separation by a solvent pair, i.e. mixture of spirit and ether at a temperature of minus 20° C.

The closest analogue of the suggested invention is an up-to-date methodology for measuring weight concentrations of asphaltenes, resins and paraffin wax in oils, which was developed by OOO <<PermNIPIneft> in conformity with GOST 8.563-96 and certified by Russia's Gosstandart's Perm Center for Standardization, Metrology and Certification (M 01-12-81). The methodology was registered in the Federal Register of Measurement Systems applicable in the state metrological monitoring and surveillance (registration code FR. 1.31.2004.00985).

### SUMMARY OF THE INVENTION

In accordance with the said methodology, the determination of three high-molecular oil components is based on a combined implementation of three methods:
1) asphaltene settlement with a petroleum ether or hexane;
2) separation of resin compounds from de-asphalted oil residue, using a complexation method with a titanium tetrachloride with a follow-up complex decomposition and resin extraction;
3) freezing out of paraffin wax from de-asphalted and de-resined oil residue.

### BRIEF DESCRIPTION OF THE DRAWINGS

FIG. 1 and FIG. 2 show free inductance drop-down curves for oil produced at existing fields.

### DETAILED DESCRIPTION OF THE INVENTION

Known methods for determination of paraffin wax and asphaltene concentration in oil are rather complex due to necessity of performing a number of operations and they are very time-consuming.

The engineering result to be achieved through the invention implementation is to obtain a simple and effective method for determination of paraffin wax and asphaltene concentration in oil, which could be applied either in laboratory conditions, or in a well in the real-time mode.

The above-mentioned engineering result is achieved through the extraction of three crude oil samples, two of which are solved in a solvent; thereafter, the solvent with light oil fractions is removed and asphaltenes are removed from one of the samples treated by the solvent. A nucleic magnetic resonance method is applied to all three samples to measure free inductance drop-down curves and to determine the ratio of solid hydrogen-containing fractions suspended in oil, to liquid hydrogen-containing fraction. The paraffin wax concentration is judged by the content of solid hydrogen-containing fractions in the solvent-treated sample, from which asphaltenes have been removed. The asphaltene concentration is judged by the content of solid hydrogen-containing fractions in another solvent-treated sample, with the consideration of the established concentration of paraffins. The concentration of paraffins and asphaltenes in the original oil is detected based on the established paraffin-to-asphaltene ratio in solid hydrogen-containing fractions.

The time of nucleic magnetic resonance signal relaxation from a solid hydrogen-containing fraction is known to be much less than the time of nucleic magnetic resonance signal relaxation from a liquid hydrogen-containing fraction; this allows to define the contribution of solid and liquid components into the cumulative free inductance drop-down curve for oil sample. Thus, the analysis of the free inductance drop-down curve for oil sample allows determination of the solid-to-liquid hydrogen-containing components ratio in it.

Virtually all suspended solid particles included in the oil composition are presented by paraffins and asphaltenes. Resins can exist in a solid state under normal conditions provided that they were separated from oil, however, when dissolved in other liquid components of oil, on the contrary to paraffin wax and asphaltenes, they become a part of a liquid phase and make a proper contribution to the nucleic magnetic resonance signal.

Other suspended solid non-hydrocarbon particles, which do not contain the ¹H atoms, but could exist in oil, make no contribution in the free inductance drop-down curve and thus can be excluded from further consideration.

To define paraffin wax and asphaltene concentration in oil, it's necessary to measure three free inductance drop-down curves for three samples: first sample is the origin in which concentration of paraffin wax and asphaltene is to be measured. Two others are the samples subjected to a special treatment, and which could be called as “de-asphalted” and <<reference>>. The following procedures are used to produce treated samples:

De-asphalted sample:
1) dissolution in solvent (e.g., in heptane/pentane/petroleum ether or other);
2) asphaltene removal;
3) solvent removal alongside with light oil fractions (optional stage that allows to increase specific weight of solid component and to decrease the volume of the sample).

Reference sample:
1) dissolution in solvent (e.g., in heptane/pentane/petroleum ether or other);
2) prevention of sediment fall-out from asphaltene (e.g., by mixing the sample);
3) solvent removal alongside with light oil fractions (optional stage that allows to increase specific weight of solid component and to decrease the volume of the sample).

The nucleic magnetic resonance analysis allows obtaining free inductance drop-down curves for all three samples.

Each free inductance drop-down curve can be split in two parts as follows: 1) signal from solid hydrogen-containing fraction suspended in oil; 2) signal from liquid hydrogen-containing oil fraction. In fact, it's possible to calculate the solid-to-liquid hydrogen-containing fraction for all three samples.

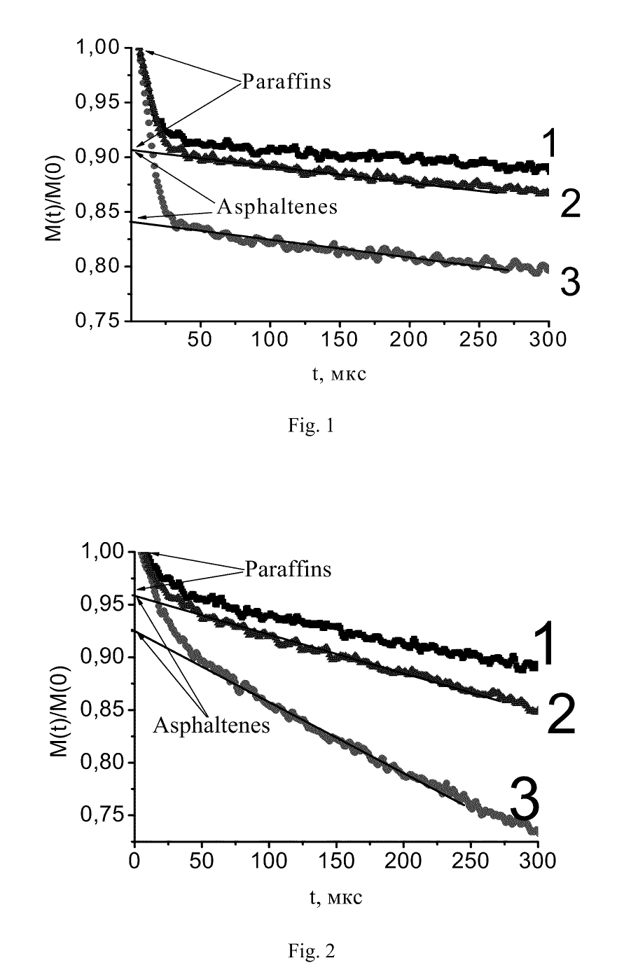

The following procedure is employed to determine the solid hydrogen-containing fraction ratio in a sample. Let's assume that normalized value of free inductance is equal to one (or 100%) and let's watch how it descends in time (FIG. 1). The free inductance drop-down curve includes two sections. At the initial section, both liquid and solid oil components contribute to the free induction value. Once several tens of microseconds have lapsed, the contribution of the solid components is not sufficient any longer. At this time point, whose exact location is different for different samples, the break in the free inductance drop-down curve becomes visible. In the second section, after the break in the curve, all remaining free inductance can be attributed to the liquid component. Therefore, by using a proper function for approximating the second section of the curve and by extending this function to a cross-section with the axis of ordinates, it's now possible to assess solid and liquid fraction shares in oil.

The straight line is the simplest example of an approximating function. For example, the de-asphaltenized oil sample produced from the first field (Curve 2, FIG. 1) contains 0.09 (9%) of solid particles and 0.91 (91%) of liquid. Exponentially vanishing approximating function could also be applied.

The whole signal from solid fractions of the de-asphaltenized oil sample is explained by a presence of paraffins. The reference sample has the same composition as the de-asphaltenized sample, plus asphaltenes which also make their contribution in a signal from the solid fractions. Thus, data comparison for the “de-asphaltenized” and “reference” samples bring information on the asphaltene and paraffin ratio in the solid fraction of oil being studied.

For example, the base oil sample, which Curve 3 from Field 1 corresponds to (ref. to FIG. 1.a), contains 0.16 (16%) of solid fraction and 0.84 (84%) of liquid fraction. Since 9% is a solid paraffin ratio, the asphaltene concentration can be estimated as 0.07 (7%), while the paraffin and asphaltene concentration ratio in the solid fraction accounts for 0.56 and 0.44, respectively.

After that, knowing the ratio of liquid and solid hydrogen-containing components in the “Original” sample and ratio (share) of paraffins and asphaltenes in the solid fractions, it's possible to calculate the concentration of paraffins and asphaltenes in original oil.

For example, as it is seen from the analysis of the free inductance drop-down curve for oil from Field 1 (curve 1, FIG. 1), the content of solid and liquid components accounts for 0.08 (8%) and 0.92 (92%), respectively. Knowing the ratio of paraffins and asphaltenes in the solid fraction, it's possible to assess the concentration of paraffins and asphaltenes in the original sample, which accounts for 4.5% and 3.5%, respectively.

The processed “De-asphaltenized” and “Reference” samples were received from crude oil by its dissolution in heptane with a follow-up heptane vaporization alongside with light fractions from the original oil. Due to vaporization of the lightest fractions, the solid-to-liquic fraction ratio in the treated samples is compared to the original one; however, data on these samples make it possible to determine the ratio of paraffins and asphaltenes in the total signal from the oil solid component. Then, knowing total concentration of the solid hydrogen-containing component in the original sample, which was obtained in the course of its nucleic magnetic resonance analysis, it's easy to calculate the concentration of paraffins and asphaltenes in it.

FIG. 2 is an additional example for oil produced from another field. The methodology we are suggesting gives the concentration of paraffins and asphaltenes in the reference sample which is equal to 4% and 3.5%, respectively. Therefore, the concentration of paraffins and asphaltenes in the original sample of oil produced from the second field accounts for 1.6% and 1.4%, respectively.

It should be noted that the nucleic magnetic resonance signal from the solid fraction of the “De-asphaltenized” sample is attributable to paraffins only. Resins existing in the samples make no contribution, since they exist in the solution in the liquid state.

The suggested methodology for detecting paraffin and asphaltene concentrations can be applied either in laboratory conditions, or implemented for online downhole measurements.

1. A method for determination of paraffin and asphaltene concentrations in oil, comprising:
asphaltene settlement with a solvent, wherein three crude oil samples are extracted;
two extracted samples are dissolved in a solvent and asphaltenes are removed from one of the solvent-treated samples; nucleic magnetic resonance method is used for measuring free inductance drop-down curves for all three samples; the ratio of solid hydrogen-containing fractions suspended in oil and to the liquid hydrogen-containing fractions is defined; based on the content of solid hydrogen-containing fractions in the solvent-treated sample, from which asphaltenes have been removed, it's possible to judge on the paraffin content;
asphaltene concentration is judged by content of solid hydrogen-containing fractions in the other solvent-treated sample, with a due consideration of the defined concentration of paraffins; paraffin and asphaltene content in the original oil is detected based on the defined paraffin-to-asphaltene ratio in solid hydrogen-containing fractions.

2. A method for determination of paraffin and asphaltene concentration in oil according to claim 1, wherein two samples are dissolved in a solvent and the solvent is removed alongside with light oil fractions.
